(19) United States
(12) Patent Application Publication
(10) Pub. No.: US 2026/0190704 A1
(43) Pub. Date: Jul. 2, 2026

(54) DISPLAY APPARATUS

(71) Applicant: LG Display Co., Ltd., Seoul (KR)

(72) Inventors: InGoo Lee, Gyeonggi-do (KR); SeHong Park, Gyeonggi-do (KR); GiBin Kim, Gyeonggi-do (KR); Kyuhwan Lee, Gyeonggi-do (KR)

(21) Appl. No.: 19/369,599

(22) Filed: Oct. 27, 2025

(30) Foreign Application Priority Data
Dec. 26, 2024 (KR) 10-2024-0197394

(51) Int. Cl. H10K 59/131; H10K 59/121; H10K 59/122; H10K 59/80

(52) U.S. Cl. CPC H10K 59/131; H10K 59/1213; H10K 59/122; H10K 59/878; H10K 59/879

(57) ABSTRACT

A display apparatus includes a substrate including a plurality of pixels, each having a plurality of subpixels; a light emission area provided on the substrate for each of the plurality of subpixels; and a wiring partially overlapping the light-emission area.

### CROSS-REFERENCE TO RELATED APPLICATIONS

Pursuant to 35 U.S.C. § 119(a), this application claims the benefit of an earlier filing date and right of priority to the Korean Patent Application No. 10-2024-0197394 filed on Dec. 26, 2024, the content of which is hereby incorporated by reference in its entirety.

### TECHNICAL FIELD

The present disclosure relates to a display apparatus displaying images.

### BACKGROUND

Since an organic light emitting display apparatus has a high response speed and low power consumption and self-emits light without requiring a separate light source, unlike a liquid crystal display apparatus, there is no viewing angle issue and thus the organic light emitting display apparatus has received attention as a next-generation flat panel display apparatus.

### SUMMARY

A display apparatus comprises a substrate comprising a plurality of pixels having a plurality of subpixels; a light emission area provided on the substrate for each of the plurality of subpixels; and a wiring partially overlapping the light-emission area.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure.

FIG. 1 is a schematic plan view of a display apparatus according to one implementation of the present disclosure.

FIG. 2 is a schematic plan view of one pixel illustrated in FIG. 1.

FIG. 3 is a schematic cross-sectional view taken along a line I-I′ illustrated in FIG. 2.

FIG. 4 is a schematic cross-sectional view taken along a line II-II′ illustrated in FIG. 2.

FIG. 5 is a schematic plan view showing one subpixel of a display apparatus according to a comparative example.

FIG. 6 is a schematic plan view showing one subpixel of the display apparatus according to one implementation of the present disclosure.

FIG. 7 is a schematic plan view showing one subpixel of the display apparatus according to the second implementation of the present disclosure.

FIG. 8 is a schematic plan view showing one subpixel of the display apparatus according to the third implementation of the present disclosure.

FIG. 9 is a schematic plan view showing one subpixel of the display apparatus according to the fourth implementation of the present disclosure.

### DETAILED DESCRIPTION OF THE DISCLOSURE

A display apparatus includes a plurality of subpixels. The plurality of subpixels include a light-emitting element layer provided in a light-emission area. The display apparatus displays an image by emitting light from the light-emitting element layer.

Meanwhile, the display apparatus has a wiring for driving each of the plurality of sub-pixels in a circuit area adjacent to the light-emission area. This is because when the wiring is provided in the light-emission area, a size (or area) of the light-emission area becomes smaller, thereby lowering the light efficiency. Therefore, display apparatus have limitations in expanding the size (or area) of the light-emission area due to the wiring, and this limits the improvement of light efficiency.

An aspect of the present disclosure is directed to providing a display apparatus in which a size (or area) of a light-emission area can be expanded.

An aspect of the present disclosure is directed to providing a display apparatus capable of improving light efficiency.

An aspect of the present disclosure is directed to providing a display apparatus in which the light extraction efficiency of light emitted from a light-emitting element layer can be improved.

An aspect of the present disclosure is directed to providing a display apparatus in which the light extraction efficiency of light emitted from a light-emitting element layer can be improved.

An aspect of the present disclosure is directed to providing a display apparatus in which the overall power consumption can be reduced by enabling light extraction in a non-light emission area.

The problems to be solved by implementations of the present disclosure are not limited to those mentioned above, and other problems not mentioned above will be apparent to those skilled in the art to which the technical ideas of the present disclosure belong from the following descriptions.

The technical benefits of the present disclosure are not limited to the above-mentioned benefits, and other benefits, which are not mentioned above, can be clearly understood by those skilled in the art from the following descriptions.

Reference will now be made in detail to the implementations of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following implementations described with reference to the accompanying drawings.

The present disclosure may, however, be embodied in different forms and should not be construed as limited to the implementations set forth herein. Rather, these implementations are provided so that this disclosure will be thorough and complete, and will fully convey the scope of the present disclosure to those skilled in the art.

A shape, a size, a ratio, an angle, and a number disclosed in the drawings for describing implementations of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary.

In construing an element, the element is construed as including an error range although there is no explicit description. In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items.

For example, the meaning of “at least one of a first item, a second item and a third item” denotes the combination of all items proposed from two or more of the first item, the second item and the third item as well as the first item, the second item or the third item.

Features of various implementations of the present disclosure may be partially or overall coupled to or combined with each other and may be variously inter-operated with each other and driven technically as those skilled in the art can sufficiently understand. The implementations of the present disclosure may be carried out independently from each other or may be carried out together in co-dependent relationship.

Hereinafter, the preferred implementations of the present disclosure will be described in detail with reference to the accompanying drawings.

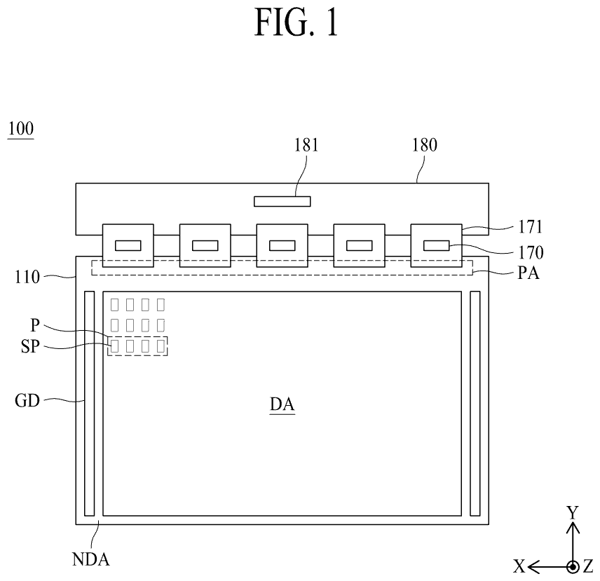

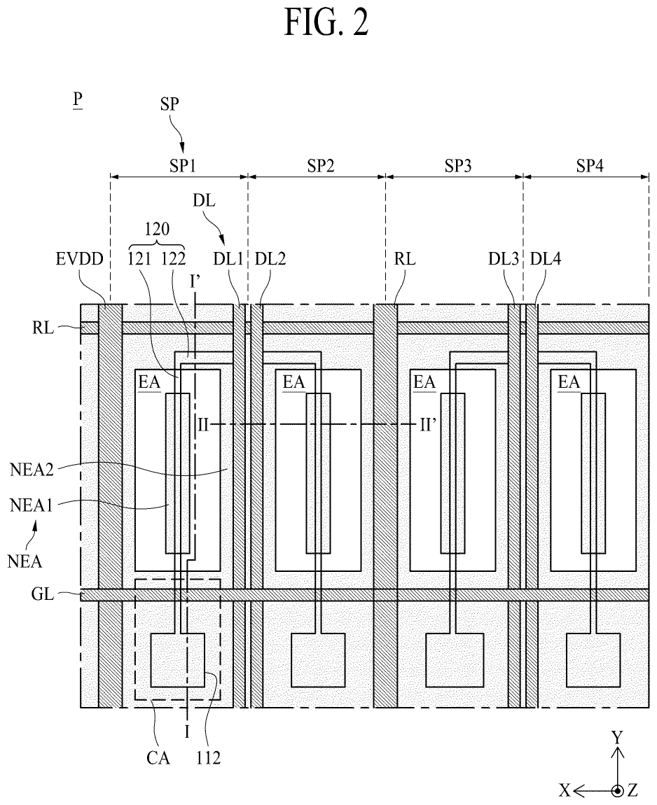

FIG. 1 is a schematic plan view of a display apparatus according to one implementation of the present disclosure, and FIG. 2 is a schematic plan view of one pixel illustrated in FIG. 1.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. The first direction (Y-axis direction) may be a direction parallel to a data wiring DL (shown in FIG. 2). The second direction (X-axis direction) may be a direction parallel to a gate wiring GL (shown in FIG. 2).

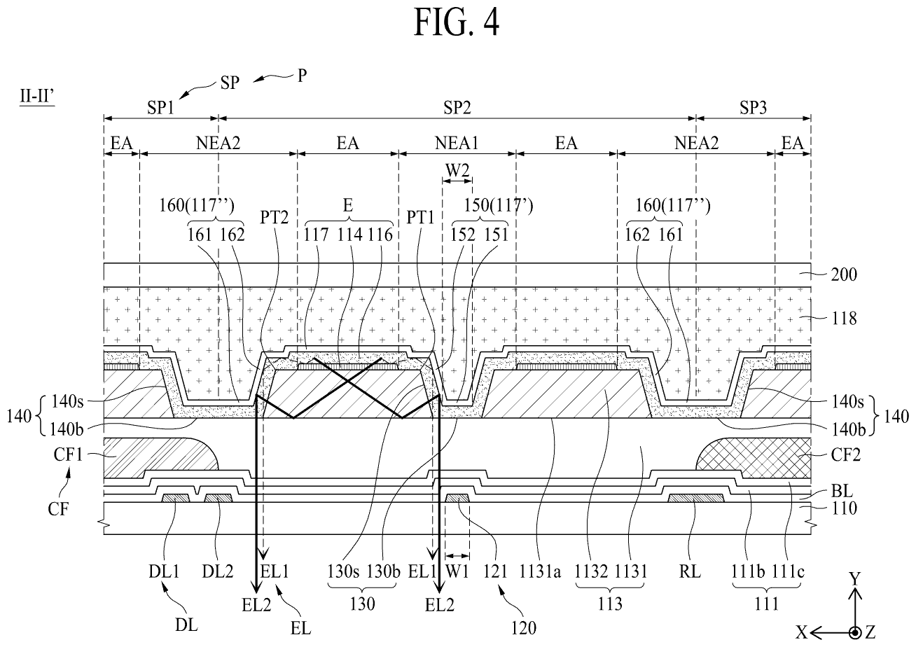

Referring to FIG. 1, a display apparatus 100 according to one implementation of the present disclosure may include a display panel having a gate driver GD. The display panel may include a substrate 110 and an opposing substrate 200 (shown in FIG. 4) bonded to each other.

The substrate 110 according to one example may include a display area DA in which a plurality of pixels P having a plurality of subpixels SP are arranged, and a non-display area NDA around the display area DA. The substrate 110 may further include a first non-light emission area NEA1, a light emission area EA, and a wiring 120. The first non-light emission area NEA1, the light emission area EA, and the wiring 120 may be provided in the display area DA of the substrate 110.

According to one example, the first non-light emission area NEA1 is provided on the substrate 110 and may be provided on an inner side of each of the plurality of sub-pixels SP. For example, as shown in FIG. 2, the first non-light emission area NEA1 may be provided on an inner side of the light emission area EA of each of the plurality of sub-pixels SP. Accordingly, the light emission area EA may be provided adjacent to the first non-light emission area NEA1. According to one example, the wiring 120 may partially overlap each of the first non-light emission area NEA1 and the light emission area EA.

In the case of a general display apparatus, a non-light emission area is not provided on an inside of each of a plurality of subpixels (or on an inside of the light-emission area). If the non-light emission area is provided on the inside of each of the plurality of subpixels (or on the inside of the light-emission area), a size (or area) of the light-emission area becomes smaller, thereby reducing light efficiency.

In contrast, the display apparatus 100 according to one implementation of the present disclosure may have light extraction by a first reflective portion 150 (shown in FIG. 4) even in the first non-light emission area NEA1 in the inner side of each of the plurality of subpixels SP, so that the light efficiency may not be reduced. Accordingly, the display apparatus 100 according to one implementation of the present disclosure may have a structural feature in which the first non-light emission area NEA1 is arranged on the inner side of each of the plurality of sub-pixels SP.

In addition, in the case of a general display apparatus, if the wiring is provided in the light-emission area, the size (or area) of the light-emission area becomes smaller, which reduces the light efficiency, so the wiring is placed in a circuit area. Therefore, in the case of the general display apparatus, the wiring does not overlap the light-emission area.

In contrast, since the display apparatus 100 according to one implementation of the present disclosure can extract light even in the first non-light emission area NEA1 by the first reflective portion 150, the light efficiency may not be reduced even if the wiring 120 partially overlaps the first non-light emission area NEA1 and the light emission area EA.

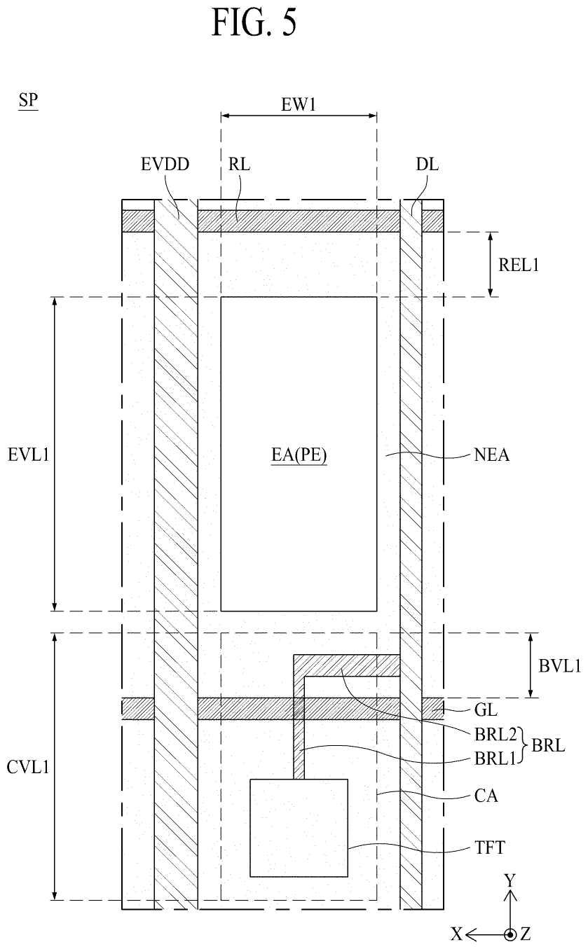

In addition, the display apparatus 100 according to one implementation of the present disclosure is provided such that the wiring 120 partially overlaps the light-emission area EA and the first non-light emission area NEA1 where light is not emitted, so that a size (or area) of the circuit area can be reduced compared to a general display apparatus, and thus a size (or area) of the light-emission area EA can be relatively expanded (or enlarged). Therefore, the display apparatus 100 according to one implementation of the present disclosure can have improved light efficiency due to the expansion of the size (or area) of the light-emission area EA. A specific description thereof will be described later with reference to FIGS. 5 to 9.

Referring to FIG. 1, a display apparatus 100 according to one implementation of the present disclosure may include a source drive integrated circuit (Hereinafter referred to as “IC”) 170, a flexible film 171, a circuit board 180, and a timing control portion 181.

The substrate 110 may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 has a smaller size than the substrate 110 and can be bonded to a remaining portion except for a pad portion of the substrate 110. The opposing substrate 200 may be an upper substrate, a second substrate, or an encapsulation substrate.

The gate driver GD supplies gate signals to the gate lines in accordance with the gate control signal input from the timing controller 190. When the source drive IC 170 is manufactured as a driving chip, the source drive IC 170 may be packaged in the flexible film 171 in a chip on film COF method or a chip on plastic COP method.

Pads, such as data pads, may be formed in the non-display area of the display panel. Lines connecting the pads with the source drive IC 170 and lines connecting the pads with lines of the circuit board 180 may be formed in the flexible film 171. The flexible film 171 may be attached onto the pads by using an anisotropic conducting film, whereby the pads may be connected with the lines of the flexible film 171.

Referring to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate wirings, data wirings, pixel power wirings, and a plurality of pixels P. Each of the plurality of pixels P may include a plurality of sub-pixels SP that may be defined by gate wirings and data wirings. Each of the plurality of sub-pixels SP may be defined as the smallest unit area where actual light is emitted.

According to one example, at least four subpixels SP arranged adjacently and configured to emit different colors among a plurality of subpixels SP constitute one unit pixel P. The one unit pixel may include, but is not limited to, a red subpixel, a green subpixel, a blue subpixel, and a white subpixel.

Each of the plurality of subpixels SP may include a thin film transistor and an organic light-emitting element connected to the thin film transistor. The subpixel may include an organic light-emitting layer (or light-emitting layer) interposed between a first electrode and a second electrode.

The organic light-emitting layer arranged in each of the plurality of subpixels SP can independently emit different color light or commonly emit white light. For example, when the organic light-emitting layer of each of the plurality of sub-pixels SP commonly emits white light, each of the red sub-pixel, the green sub-pixel, and the blue sub-pixel may include a color filter CF (or wavelength conversion member CF) that converts the white light into light of a different color. In this case, the white subpixel according to one example may not have a color filter. The color filter CF according to one example may include a red color filter CF1 (shown in FIG. 4), a blue color filter CF2 (shown in FIG. 4), and a green color filter.

In a display apparatus 100 according to one implementation of the present disclosure, an area provided with the red color filter CF1 may be a red subpixel SP1, an area provided with the blue color filter CF2 may be a blue subpixel SP3, an area provided with the green color filter may be a green subpixel SP4, and an area without the color filter may be a white subpixel SP2. In the present disclosure, the red subpixel SP1 may be represented as a first subpixel equipped to emit red light, the blue subpixel SP3 may be represented as a third subpixel equipped to emit blue light, the green subpixel SP4 may be represented as a fourth subpixel equipped to emit green light, and the white subpixel SP2 may be represented as a second subpixel equipped to emit white light.

Each of the subpixels SP supplies a predetermined current to the organic light emitting element in accordance with a data voltage of the data wiring when a gate signal is input from the gate line by using the thin film transistor. For this reason, the light emitting layer of each of the subpixels may emit light with a predetermined brightness in accordance with the predetermined current.

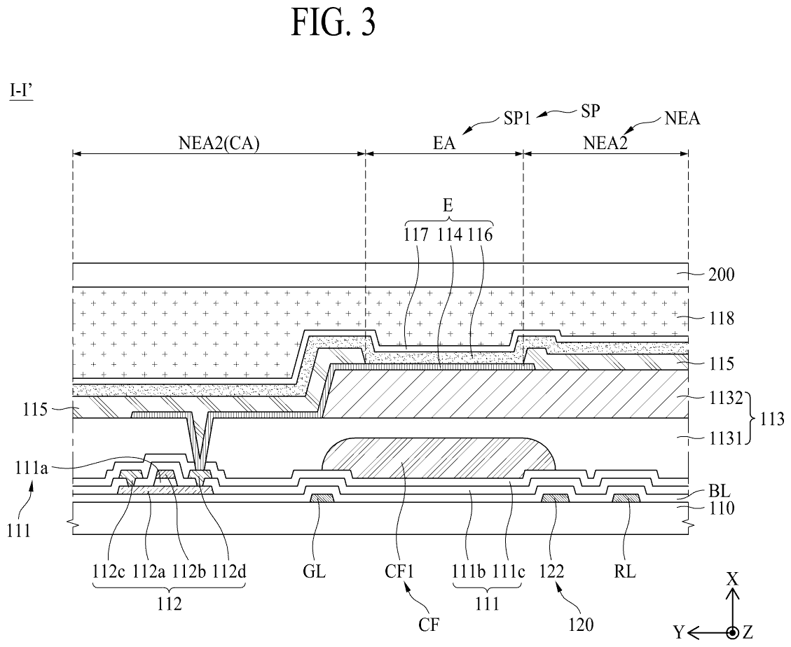

FIG. 3 is a schematic cross-sectional view taken along a line I-I′ illustrated in FIG. 2, and FIG. 4 is a schematic cross-sectional view taken along a line II-II′ illustrated in FIG. 2.

As shown in FIGS. 2 and 3, the display area DA may include a light emission area EA and a non-light emission area NEA. The light emission area EA is the area where light is emitted by the organic light-emitting element layer E. The non-light emission area NEA is the area that does not transmit most of the light incident from the outside.

For example, the non-light emission area NEA may be an area excluding the light emission area EA where light is emitted. In one example, the non-light emission area NEA may include a circuit area CA (shown in FIG. 3). The circuit area CA may include a thin film transistor 112 for driving each of the plurality of subpixels SP (or the organic light emitting element layer E of each of the plurality of subpixels SP).

In the display apparatus 100 according to one implementation of the present disclosure, the non-light emission area NEA may include a first non-light emission area NEA1 and a second non-light emission area NEA2.

According to one example, the first non-light emission area NEA1 may be provided on the inner side of each of the plurality of sub-pixels SP. For example, as shown in FIG. 2, the inner side of each of the plurality of sub-pixels SP may mean an inner side of the light emission area EA included in one sub-pixel SP. The organic light-emitting element layer E (shown in FIG. 4) may not be arranged in the first non-light emission area NEA1.

According to one example, the second non-light emission area NEA2 may be provided on an outer side of each of the plurality of subpixels SP. For example, as shown in FIG. 2, the outer side of each of the plurality of subpixels SP may mean an outer side of the light emission area EA. The outer side of each of the plurality of subpixels SP may include a circuit area CA adjacent to the light emission area EA. Additionally, the outer side of each of the plurality of subpixels SP may include a region between the plurality of subpixels SP (e.g., pixel electrodes 114 of each of the first subpixel SP1 and the second subpixel SP2) that emit light of different colors.

Additionally, in the non-light emission area NEA, the plurality of pixels P and a plurality of lines for driving each of the plurality of pixels P can be disposed. The plurality of lines, according to one example, can include a plurality of first signal lines and a plurality of second signal lines.

The plurality of first signal lines may be extended in the second direction (X-axis direction). Each of the plurality of first signal lines may include at least one gate line GL (or scan line).

The plurality of second signal lines can extend in the first direction (Y-axis direction). The plurality of second signal lines can intersect with the plurality of first signal lines. Each of the plurality of second signal lines may include a pixel power line EVDD, a plurality of data wirings DL, and a reference wiring RL. The plurality of data wirings DL can include a first data wiring for driving the first sub-pixel SP1, a second data wiring for driving the second sub-pixel SP2, a third data wiring for driving the third sub-pixel SP3, and a fourth data wiring for driving the fourth sub-pixel SP4.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

The display apparatus 100 according to one implementation of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images.

According to one example, the pad portion PA may be placed in the non-display area NDA (or the first non-display area NDA1) above the display area DA based on FIG. 1. Since the first non-display area is formed above the display area DA, it can be expressed in terms of an upper non-display area.

The gate driver GD supplies gate signals to the gate lines in accordance with the gate control signal input from the timing controller 181. The gate driver GD may be formed on one side of the display area DA of the display panel or on the non-display area NDA outside both sides of the display area DA in a gate driver in panel GIP method as shown in FIG. 1.

The plurality of gate drivers GD may be separately disposed on a left side of the display area DA, that is, the second non-display area and a right side of the display area DA, that is, the third non-display area. Since each of the second non-display area and the third non-display area is formed on a side of the display area DA, it can be expressed in terms of side non-display areas.

According to one example, the plurality of gate drivers GD may be connected to the plurality of pixels P and the plurality of first signal lines for supplying signals to the plurality of pixels P. The plurality of first signal lines may include at least one signal line for supplying a signal for driving the pixel P.

The plurality of second signal lines may be extended in the first direction (Y-axis direction). The plurality of second signal lines may include a pixel power line EVDD and at least one data wiring DL to supply a data voltage to the pixel P. Each of the plurality of second signal lines may be connected to at least one of a plurality of pads, a pixel power shorting bar, and a common power shorting bar. The pixel power shorting bar and the common power shorting bar can be arranged in a fourth non-display area facing a pad portion PA based on the display area DA. Since the fourth non-display area is formed below the display area DA, it can be expressed in terms of a lower non-display area.

The pixels P are provided to overlap at least one of the first signal line or the second signal line and emit predetermined light to display an image. The light emission area EA may correspond to an area, which emits light, in the pixel P.

Referring to FIG. 3, the non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

According to one implementation of the present disclosure, the display apparatus 100 can reduce the size (or area) of the circuit area CA by arranging wiring 120 in the first non-light emission area NEA1 which is a dead zone. Accordingly, the display apparatus 100 according to one implementation of the present disclosure can reduce the size (or area) of the circuit area CA, so that the size (or area) of the light-emission area EA can be relatively expanded (or enlarged), thereby improving light efficiency.

The wiring 120 according to one example may be a data branch wiring that applies a data signal to the thin film transistor 112. Accordingly, as shown in FIG. 2, the wiring 120 can be connected to each of the thin film transistor 112 in the circuit area CA and the data wiring DL in the second non-light emission area NEA2. According to one example, the wiring 120 can include a first wiring 121 and a second wiring 122.

As shown in FIG. 2, the wiring 120 is connected to the circuit area CA and can extend in the first direction (Y-axis direction) from the circuit area CA toward the reference line RL. In this case, the wiring 120 can partially overlap the first non-light emission area NEA1 and the light emission area EA. For example, as shown in FIG. 2, the wiring 120 extended from a circuit area CA can sequentially pass through (or overlap) the light-emission area EA (or a lower light-emission area EA), the first non-light emission area NEA1, and the light-emission area EA (or an upper light-emission area EA). The wiring 120 that sequentially passes through (or overlaps) the light-emission area EA, the first non-light emission area NEA1, and the light-emission area EA can be bent parallel to the reference line RL and connected to the data wiring DL (or a first data wiring DL1).

The first wiring 121 may be a wiring that partially overlaps the first non-light emission area NEA1 and the light emission area EA. As shown in FIG. 2, the first wiring 121 may be a wiring arranged in the first direction (Y-axis direction). The second wiring 122 may be a wiring that is connected to an end of the first wiring 121 and connected to the data wiring DL (or the first data wiring DL1) in the second non-light emission area NEA2. That is, the second wiring 122 may be a wiring that is connected to the first wiring 121 and is arranged in a different direction (e.g., the second direction (X-axis direction)) from the first wiring 121.

Hereinafter, with reference to FIG. 3, the structure of each of the plurality of sub-pixels SP will be described in detail.

Referring to FIG. 3, the display apparatus 100 according to one implementation of the present disclosure can include a buffer layer BL, a plurality of inorganic films 111, a thin film transistor 112, a color filter CF, a planarization layer 113, a pixel electrode 114, a bank 115, an organic light emitting layer 116, a cathode electrode 117, and an encapsulation layer 118.

Each of the subpixels SP according to one implementation may include the plurality of inorganic films 111 provided on an upper surface of the buffer layer BL, including a gate insulating layer 111a, an interlayer insulating layer 111b, and a passivation layer 111c.

Also, each of the subpixels SP may include a color filter CF provided on the plurality of inorganic films 111, a planarization layer 113 provided on the color filter CF. The planarization layer 113 may include a first planarization layer 1131 and a second planarization layer 1132. The second planarization layer 1132 may be disposed on the first planarization layer 1131. A pixel electrode 114 may be disposed on the second planarization layer 1132.

Each of the subpixels SP may further include a bank 115 covering one edge of the pixel electrode 114, an organic light-emitting layer 116 on the pixel electrode 114 and the bank 115, and a cathode electrode 117 on the organic light-emitting layer 116. The encapsulation layer 118 may be placed on the cathode electrode 117.

The thin film transistor 112 for driving of subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, the interlayer insulating layer 111b, and the passivation layer 111c. The pixel electrode 114, the organic light emitting layer 116 and the cathode electrode 117 may be included in a light emitting element layer E.

The buffer layer BL may be formed between the substrate 110 and the gate insulating layer 111a to protect the thin film transistor 112 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 3, in the circuit area CA and the subpixel SP.

The source electrode 112c may be electrically connected to the source area of the active layer 112a through a source contact hole provided in the interlayer insulating layer overlapped with the source area of the active layer 112a.

The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

Additionally, the thin film transistor provided in the pixel area may have a characteristic in which the threshold voltage is shifted by light. To prevent this, the display panel or the substrate 110 may further include a light-shielding layer LS provided under the active layer 112a of at least one of the thin film transistor 112, a first switching thin film transistor, and a second switching thin film transistor.

The light-shielding layer LS is provided between the substrate 110 and the active layer 112a to block light incident on the active layer 112a through the substrate 110, thereby minimizing changes in the threshold voltage of the transistor caused by external light. In addition, the light shielding layer LS may be provided between the substrate 110 and the active layer 112a to prevent the thin film transistor from being visible to the user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

The color filter CF may be placed on the passivation layer 111c. For example, the color filter CF may be placed between the plurality of inorganic films 111 and the first planarization layer 1131. The color filter CF may include a red color filter CF1 arranged in the red subpixel SP1, a blue color filter CF2 arranged in the blue subpixel SP3, and a green color filter arranged in the green subpixel SP4. Since the white subpixel SP2 is provided to emit white light, it may not include the color filter.

The planarization layer 113 may be provided on the substrate 110 to cover the passivation layer 111c and the color filter CF. According to one example, the planarization layer 113 may be placed between the substrate 110 and the pixel electrode 114. The planarization layer 113 may be formed in the entire circuit area CA in which the thin film transistor 112 is disposed and the entire light emission area EA. In addition, the planarization layer 113 may be formed in the other non-display area NDA except a pad area PA of the non-display area NDA and the entire display area DA. For example, the planarization layer 113 may include an extension portion (or an enlarged portion) extended or enlarged from the display area DA to the other non-display area NDA except the pad area PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

The planarization layer 113 may include a first planarization layer 1131 and a second planarization layer 1132 disposed on the first planarization layer 1131. The first planarization layer 1131 may be disposed on the substrate 110. The second planarization layer 1132 may be disposed on the first planarization layer 1131. According to one example, the second planarization layer 1132 may be disposed between the first planarization layer 1131 and the pixel electrode 114.

As shown in FIG. 4, the first planarization layer 1131 is provided to cover the passivation layer 111c and the color filter CF, so that it can be formed continuously across the plurality of subpixels SP. In contrast, the second planarization layer 1132 can be formed discontinuously by forming a first pattern portion 130 on the inner side of the plurality of subpixels SP and a second pattern portion 140 on the outer side (or between the plurality of subpixels SP) of the plurality of subpixels SP. Accordingly, as shown in FIG. 4, the plurality of second planarization layers 1132 can be provided in an island shape on the first planarization layer 1131.

Referring to FIG. 3 and FIG. 4, an upper surface of the second planarization layer 1132 can be provided flat. Accordingly, the pixel electrode 114 on the second planarization layer 1132 can also be provided flat, and the organic light-emitting layer 116 and the cathode electrode 117 formed thereon can also be provided in a flat form. Since the pixel electrode 114, the organic light-emitting layer 116, and the cathode electrode 117, i.e., the organic light-emitting element layer E, are provided flatly in the light-emission area EA, a thicknesses of the pixel electrode 114, the organic light-emitting layer 116, and the cathode electrode 117 can be formed uniformly within the light-emission area EA. Accordingly, the organic light-emitting layer 116 can emit light uniformly without deviation within the light-emission area EA.

The pixel electrode 114 may be formed on the second planarization layer 1132. As shown in FIG. 3, the pixel electrode 114 may be connected to the drain electrode or source electrode of the thin film transistor through a contact hole penetrating the first planarization layer 1131 and the passivation layer 111c. An edge portions on both sides of the pixel electrode 114 may be covered by the bank 115. Since FIG. 3 is a cross-sectional view in the first direction (Y-axis direction), the bank 115 may be provided to cover an upper and lower edges of the pixel electrode 114 respectively based on a plane (e.g., FIG. 2). In contrast, as shown in FIG. 4, the bank 115 may not be arranged between the plurality of sub-pixels SP. Accordingly, the display apparatus 100 according to one implementation of the present disclosure may be provided with a bankless structure in which the bank 115 is not arranged between the plurality of sub-pixels SP arranged in the second direction (X-axis direction).

The pixel electrode 114 may be made of at least one of a transparent metal material or a semi-transmissive metal material.

Because the display apparatus 100 according to an implementation of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 may be an area, which does not emit light, and can be placed adjacent to the light emission area EA of each of the plurality of sub-pixels SP. For example, the bank 115 may be disposed in the non-light emission area NEA (or the second non-light emission area NEA2 on an upper and lower sides of the pixel electrode 114). The bank 115 may be formed to cover a portion where the edge of the pixel electrode 114. Accordingly, the bank 115 may prevent the pixel electrode 114 and the cathode electrode 117 in the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrode 114 and the bank 115. Thus, the bank 115 may be partially provided between the pixel electrode 114 and the organic light emitting layer 116. The bank 115 can be expressed in terms of a pixel definition films. The bank 115 according to one example may comprise organic material and/or inorganic material.

The organic light emitting layer 116 may be formed on the pixel electrode 114 and the bank 115. The organic light emitting layer 116 can be placed under the cathode electrode 117. According to one example, the organic light emitting layer 116 may be disposed in the light emission area EA and the non-light emission area NEA (or the first non-light emission area NEA1 and the second non-light emission area NEA2). The organic light emitting layer 116 may be provided between the pixel electrode 114 and the cathode electrode 117. Thus, when a voltage is applied to each of the pixel electrode 114 and the cathode electrode 117, an electric field is formed between the pixel electrode 114 and the cathode electrode 117. Therefore, the organic light emitting layer 116 may emit light. The organic light emitting layer 116 may be formed of a plurality of subpixels SP and a common layer provided on the bank 115.

The organic light emitting layer 116 according to one implementation may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an implementation of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The cathode electrode 117 may be formed on the organic light emitting layer 116. The cathode electrode 117 may be arranged in the non-display area NDA (or a part of the non-display area NDA) and the display area DA. In the display area DA, the cathode electrode 117 may be arranged in the light emission area EA and the non-light emission area NEA (or the first non-light emission area NEA1 and the second non-light emission area NEA2). That is, the cathode electrode 117 may be arranged to cover the entire display area DA. As a result, the cathode electrode 117 may be arranged to have a size larger than the display area DA and smaller than the substrate 110. Accordingly, the cathode electrode 117 can be placed in the non-display area NDA (or the part of the non-display area NDA) and the display area DA.

The cathode electrode 117 according to one example may include a metal material. The cathode electrode 117 may reflect the light emitted from the organic light emitting layer 116 in the plurality of subpixels SP toward a lower surface of the substrate 110. Therefore, the display apparatus 100 according to one implementation of the present disclosure may be implemented as a bottom emission type display apparatus.

The display apparatus 100 according to one implementation of the present disclosure is a bottom emission type and has to reflect light emitted from the light emitting layer 122 toward the substrate 110, and thus the cathode electrode 117 may be made of a metal material having high reflectance. The cathode electrode 117 according to one example may be formed of a metal material having high reflectance such as a silver (Ag), na aluminum (Al), a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The cathode electrode 117 may be expressed as terms such as a second electrode, an opposing electrode and a reflective electrode.

The encapsulation layer 118 is formed on the cathode electrode 117. The encapsulation layer 118 serves to prevent oxygen or moisture from penetrating into the organic light emitting layer 116 and the cathode electrode 117. The encapsulation layer 118 can comprise a plurality of layers including at least one inorganic film and at least one organic film. The encapsulation layer 118 may further contain an absorbent material for absorbing moisture or oxygen to enhance the moisture-proofing effect. For example, the absorbent material may be a getter.

On the other hand, as shown in FIG. 3, the encapsulation layer 118 can be disposed not only in the light emission area EA but also in the non-light emission area NEA. The encapsulation layer 118 can be disposed between the cathode electrode 117 and the opposing substrate 200.

In the display apparatus 100 according to one implementation of the present disclosure, the first planarization layer 1131 may be provided to have a different refractive index from the second planarization layer 1132. For example, a refractive index of the second planarization layer 1132 may be provided to be greater than a refractive index of the first planarization layer 1131. Accordingly, as illustrated in FIG. 4, light emitted from the organic light-emitting layer 116 and directed toward the substrate 110 may be totally reflected due to a difference in refractive index between the second planarization layer 1132 and the first planarization layer 1131, and the light path may be changed toward a first reflective portion 150 and a second reflective portion 160. Accordingly, the light that has formed a path toward the first reflective portion 150 and the second reflective portion 160 can be reflected by the first reflective portion 150 and the second reflective portion 160 and emitted in the form of a front-extracted light of the subpixel SP that emits light. Hereinafter, the light reflected by the first reflective portion 150 and the second reflective portion 160 and emitted toward the substrate 110 is defined as a reflected light EL.

As shown in FIG. 4, the reflected light EL may include a first reflected light EL1 and a second reflected light EL2.

The first reflected light EL1 may be a front extraction light that is emitted from the organic light-emitting layer 116, is wave-guided through total reflection (and/or total reflection between the cathode electrode 117 and the second planarization layer 1132) between the pixel electrode 114 and the cathode electrode 117, and then reflected by the first reflective portion 150 and the second reflective portion 160 and is emitted to the substrate 110. Since the first reflected light EL1 is the light that is wave-guided, it can be expressed in terms of a WG mode extracted light EL1.

The second reflected light EL2 may be a front extraction light that is emitted from the organic light-emitting layer 116, totally reflected at a boundary between the first planarization layer 1131 and the second planarization layer 1132, and then reflected by the first reflective portion 150 and the second reflective portion 160 and emitted to the substrate 110. Since the second reflected light EL2 emits light that is totally reflected and disappears by the substrate 110, it can be expressed in terms of a substrate mode extracted light EL2.

Meanwhile, in the case of a general display apparatus, a non-light emission area is not provided inside a light-emission area. This is because if the non-light emission area is provided inside the light-emission area, a size (or area) of the light-emission area is reduced, thereby lowering a light efficiency. Therefore, in the case of the general display apparatus, the non-light emission area is not provided inside the light emission area. However, light emitted from the light emission area can be totally reflected between the pixel electrode and the cathode electrode and wave-guided, and the wave-guided light can be extinguished while going through multiple total reflection processes. As the area of the light emission area increases, a number of times the light extinguished by the wave-guided is totally reflected increases, so the light efficiency decreases.

According to one implementation of the present disclosure, the display apparatus 100 has a first non-light emission area NEA1 provided on the inner side (or on the inner side of the light emission area EA of each of the plurality of sub-pixels SP) of each of the plurality of sub-pixels SP, so that the light emission area EA can be partially disconnected. Accordingly, the display apparatus 100 according to one implementation of the present disclosure can minimize light dissipated by the wave-guided and instead emit light waved through the first reflective portion 150 provided in the first non-light emission area NEA1 to the outside, so that light efficiency can be improved.

Referring again to FIG. 4, in the display apparatus 100 according to one implementation of the present disclosure, the first non-light emission area NEA1 may include the first planarization layer 1131, the second planarization layer 1132, the first pattern portion 130, and the first reflective portion 150. As described above, the first planarization layer 1131 may be provided on the substrate 110, and the second planarization layer 1132 may be provided on the first planarization layer 1131. The first pattern portion 130 may be provided on the second planarization layer 1132. The first reflective portion 150 may be provided on the first pattern portion 130.

According to one example, the first pattern portion 130 may be formed concavely in the second planarization layer 1132. For example, the first pattern portion 130 may be formed by patterning and removing a portion of the second planarization layer 1132 on the inner side of each of the plurality of subpixels SP. Accordingly, the first pattern portion 130 may be expressed in terms of a groove, a slit, a trench, an overcoat layer slit, and an overcoat layer trench on the inner side of each of the plurality of subpixels SP.

As shown in FIG. 4, the first pattern portion 130 may be arranged spaced apart from the light-emission area EA. According to one example, the first pattern portion 130 may be provided on the inside of the plurality of subpixels SP (or light-emission area EA) in the form of the slit or the trench. A width of the first pattern portion 130 may be formed to decrease in the direction from the first reflective portion 130 toward the substrate 110 (or in the direction from the pixel electrode 114 toward the substrate 110).

As shown in FIG. 4, the first pattern portion 130 may include an inclined surface 130s that is arranged at an angle with respect to an upper surface of the substrate 110, and a bottom surface 130b that extends from the inclined surface 130s and is arranged parallel to the upper surface of the substrate 110. The inclined surface 130s may be an inclined surface of the second planarization layer 1132. The bottom surface 130b may be a part of an upper surface 1131a of the first planarization layer 1131.

As illustrated in FIG. 4, the first pattern portion 130 may be provided with the inclined surface 130s of the second planarization layer 1132 and the bottom surface 130b of the first planarization layer 1131, but is not necessarily limited thereto. The first pattern portion 130 according to another example may be formed only on the second planarization layer 1132. In this case, the inclined surface of the first pattern portion 130 may be an inclined surface of the second planarization layer 1132, and the bottom surface of the first pattern portion 130 may be a bottom surface of the second planarization layer 1132.

According to one example, the first reflective portion 150 may be placed on the first pattern portion 130. The first reflective portion 150 is formed of a material capable of reflecting light, and thus may reflect light emitted from the light-emission area EA and wave-guided and/or light totally reflected at an interface between the first planarization layer 1131 and the second planarization layer 1132 toward a front side of a light-emitting subpixel SP. The first reflective portion 150 may be formed along the profile of the first pattern portion 130 that is concavely formed in the first non-light emission area NEA1. As illustrated in FIG. 4, the first reflective portion 150 is a part of the cathode electrode 117 disposed in the first non-light emission area NEA1, and thus may be indicated by the drawing symbol 117′.

According to one example, the first reflective portion 150 may include a first flat reflective portion 151 and a first inclined reflective portion 152. The first flat reflective portion 151 may be arranged parallel to the upper surface of the substrate 110. The first inclined reflective portion 152 may be connected to the first flat reflective portion 151 and arranged at an angle.

As illustrated in FIG. 4, the first flat reflective portion 151 may be arranged parallel to the upper surface of the substrate 110 on the first pattern portion 130 between two light-emission areas EA (or two light-emission areas EA in a cross-sectional view) provided in one subpixel SP (e.g., the second subpixel SP2), that is, in the first non-light emission area NEA1. Accordingly, the first flat reflective portion 151 may be expressed in terms of a flat reflective portion located an inner side of each of the plurality of subpixels SP.

The first inclined reflective portion 152 may be arranged inclinedly on the first pattern portion 130 in the first non-light emission area NEA1. Therefore, the first inclined reflective portion 152 may be expressed in terms of a side reflective portion or an inclined reflective portion located on an inner side of each of the plurality of subpixels SP.

Therefore, the display apparatus 100 according to one implementation of the present disclosure is provided with the reflective portion (or the first reflective portion 150) arranged in the non-light emission area NEA (or the first non-light emission area NEA1) provided on the inner side of each of the plurality of sub-pixels SP, so that light extraction can be achieved even in the non-light emission area NEA (or the first non-light emission area NEA1), and thus light efficiency can be improved.

Referring to FIG. 4, in a display apparatus 100 according to one implementation of the present disclosure, the second non-light emission area NEA2 may include a second pattern portion 140 and a second reflective portion 160. The second pattern portion 140 may be concavely formed in the second planarization layer 1132. The second reflective portion 160 may be provided on the second pattern portion 140.

According to one example, the second pattern portion 140 may be formed concavely in the second planarization layer 1132. For example, the second pattern portion 140 may be formed by patterning and removing a portion of the second planarization layer 1132 on the outer side of each of the plurality of subpixels SP. Accordingly, the second pattern portion 140 may be expressed in terms of a groove, a slit, a trench, an overcoat layer slit, and an overcoat layer trench on the outer side of each of the plurality of subpixels SP.

As shown in FIG. 4, the second pattern portion 140 may be arranged spaced apart from the light-emission area EA. According to one example, the second pattern portion 140 may be provided on the outer side of the plurality of subpixels SP (or light-emission area EA) in the form of the slit or the trench. A width of the second pattern portion 140 may be formed to decrease in the direction (or in the direction from the pixel electrode 114 toward the substrate 110) from the second reflective portion 160 toward the substrate 110.

As shown in FIG. 4, the second pattern portion 140 may include an inclined surface 140s that is arranged at an angle with respect to the upper surface of the substrate 110, and a bottom surface 140b that extends from the inclined surface 140s and is arranged parallel to the upper surface of the substrate 110. The inclined surface 140s of the second pattern portion 140 may be an inclined surface of the second planarization layer 1132. The bottom surface 140b of the second pattern portion 140 may be a part of an upper surface 1131a of the first planarization layer 1131.

As shown in FIG. 4, the second pattern portion 140 may be provided with the inclined surface 140s of the second planarization layer 1132 and the bottom surface 140b of the first planarization layer 1131, but is not necessarily limited thereto. The second pattern portion 140 according to another example may be formed only on the second planarization layer 1132. In this case, the inclined surface of the second pattern portion 140 may be an inclined surface of the second planarization layer 1132, and the bottom surface of the second pattern portion 130 may be a bottom surface of the second planarization layer 1132.

According to one example, the second reflective portion 160 may be placed on the second pattern portion 140. The second reflective portion 160 is formed of a material capable of reflecting light, and thus may reflect light emitted from the light-emission area EA and wave-guided and/or light totally reflected at the interface between the first planarization layer 1131 and the second planarization layer 1132 toward a front side of the light-emitting subpixel SP. The second reflective portion 160 may be formed along the profile of the second pattern portion 140 that is concavely formed in the second non-light emission area NEA2. As illustrated in FIG. 4, the second reflective portion 160 is a part of the cathode electrode 117 disposed in the second non-light emission area NEA2, and thus may be indicated by the drawing symbol 117″.

According to one example, the second reflective portion 160 may include a second flat reflective portion 161 and a second inclined reflective portion 162. The second flat reflective portion 161 may be arranged parallel to the upper surface of the substrate 110. The second inclined reflective portion 162 may be connected to the second flat reflective portion 161 and arranged at an angle.

As illustrated in FIG. 4, the second flat reflective portion 161 may be arranged parallel to the upper surface of the substrate 110 on the second pattern portion 140 in the second non-light emission area NEA2 between two subpixels SP, for example, between the first subpixel SP1 and the second subpixel SP2. Accordingly, the second flat reflective portion 161 may be expressed in terms of a flat reflective portion located on the outer side of each of the plurality of subpixels SP.

The second inclined reflective portion 162 may be arranged inclinedly on the second pattern portion 140 in the second non-light emission area NEA2. Therefore, the second inclined reflective portion 162 may be expressed in terms of a side reflective portion or an inclined reflective portion located on the outer side of each of the plurality of subpixels SP.

Therefore, the display apparatus 100 according to one implementation of the present disclosure is provided with the reflective portion (or the second reflective portion 160) positioned in the non-light emission area NEA (or the second non-light emission area NEA2) provided on the outer side of the plurality of sub-pixels SP, so that the light directed toward an adjacent sub-pixel SP can be reflected by the reflective portion (or the second reflective portion 160), thereby improving light extraction efficiency.

As a result, since the display apparatus 100 according to the present disclosure can extract light even in the non-light emission area NEA through the reflective portions (or the first reflective portion 150 and the second reflective portion 160) provided on the inner and outer sides of each of the plurality of subpixels SP, the display apparatus can have the same light-emitting efficiency or improve the light-emitting efficiency to a greater extent with lower power compared to a display apparatus having no reflective portions on the inner and outer sides of each of the plurality of subpixels, so that the overall power consumption can be reduced.

Meanwhile, in the display apparatus 100 according to one implementation of the present disclosure, the size (or area) of the circuit area CA can be reduced by arranging the wiring 120 (or the first wiring 121) in the first non-light emission area NEA1, which is a dead zone, and thus the size (or area) of the light emission area EA can be expanded. Accordingly, as shown in FIG. 4, the display apparatus 100 according to one implementation of the present disclosure can have a structural feature in which the wiring 120 (or the first wiring 121) overlaps the first flat reflective portion 151.

In the display apparatus 100 according to one implementation of the present disclosure, a width W1 of the wiring 120 (or the first wiring 121) may be provided to be equal to or narrower than a width W2 of the first flat reflective portion 151. If the width W1 of the wiring 120 (or the first wiring 121) is wider than the width W2 of the first flat reflective portion 151, the wiring 120 (or the first wiring 121) blocks the reflected light emitted in the front direction by being reflected by the first inclined reflective portion 152. Accordingly, the display apparatus 100 according to one implementation of the present disclosure is provided with the width W1 of the wiring 120 (or the first wiring 121) equal to or narrower than the width W2 of the first flat reflective portion 151, so that the reflected light reflected and emitted by the first inclined reflective portion 152 is not obstructed, thereby improving light extraction efficiency.

Referring to FIG. 4, the substrate 110 may include a data wiring DL (or a second data wiring DL2) partially overlapping with the second flat reflective portion 161. As in FIG. 2, the data wiring DL (or the second data wiring DL2) may be connected to the wire 120. Since the wiring 120 is connected to the thin film transistor 112 of the circuit area CA, the data wiring DL (or the second data wiring DL2) can be connected to the thin film transistor 112 through the wiring 120. Accordingly, a data signal (or data power) applied from the pad portion PA to the data wiring DL (or the second data wiring DL2) can be applied to the thin film transistor 112 through the wiring 120.

In the display apparatus 100 according to one implementation of the present disclosure, the pixel electrode 114 of each of the plurality of subpixels SP may be arranged spaced apart from the first reflective portion 150 of each of the plurality of subpixels SP. For example, with reference to FIG. 4, the pixel electrode 114 of the second subpixel SP2 may be arranged spaced apart from the first reflective portion 150 provided in the first non-light emission area NEA1 in the second direction (X-axis direction) by a predetermined distance. Since the first reflective portion 150 is a cathode electrode 117′ arranged on the first pattern portion 130, the pixel electrode 114 can be arranged to be spaced apart from a first point PT1 connecting the upper surface of the second planarization layer 1132 and the inclined surface 130s of the first pattern portion 130 by a distance between an end (or a right end of the pixel electrode 114) of the pixel electrode 114.

If the pixel electrode 114 is not positioned apart from the first reflective portion 150, the pixel electrode 114 may be formed on the inclined surface 130s of the first pattern portion 130 when the pixel electrode 114 is formed. In this case, light emission can occur even on the inclined surface 130s of the first pattern portion 130, and the emitted light can be emitted toward a subpixel SP (e.g., the third subpixel SP3) of a different color, thereby causing color mixing.

Therefore, in the display apparatus 100 according to one implementation of the present disclosure, the pixel electrode 114 of each of the plurality of subpixels SP is arranged spaced apart from the first reflective portion 150, thereby preventing the occurrence of color mixing.

Meanwhile, the first reflective portion 150 may be partially positioned closer to the substrate 110 than the pixel electrode 114. For example, as shown in FIG. 4, the first flat reflective portion 151 and a part of the first inclined reflective portion 152 of the first reflective portion 150 may be positioned closer to the substrate 110 than the pixel electrode 114. The display apparatus 100 according to one implementation of the present disclosure is a bottom-emitting type, and light extraction efficiency can be improved through the first reflective portion 150 (or the first inclined reflective portion 152) on the first pattern portion 130 concavely formed on the inner side of the subpixel SP. Accordingly, the display apparatus 100 according to one implementation of the present disclosure may have a structural feature in which the first flat reflective portion 151 of the first reflective portion 150 and the part of the first inclined reflective portion 152 are positioned closer to the substrate 110 than to the pixel electrode 114.

Referring again to FIG. 4, in the display apparatus 100 according to one implementation of the present disclosure, the pixel electrode 114 of each of the plurality of subpixels SP may be arranged spaced apart from the second reflective portion 160 of each of the plurality of subpixels SP. For example, with reference to FIG. 4, the pixel electrode 114 of the second subpixel SP2 may be positioned a predetermined distance apart in the second direction (X-axis direction) from the second reflective portion 160 provided in the second non-light emission area NEA2. Since the second reflective portion 160 is a cathode electrode 117″ arranged on the second pattern portion 140, the pixel electrode 114 can be arranged to be spaced apart from a second point PT2 connecting the upper surface of the second planarization layer 1132 and the inclined surface 140s of the second pattern portion 140 by a distance between an end (or a left end of the pixel electrode 114) of the pixel electrode 114.

If the pixel electrode 114 is not arranged to be spaced apart from the second reflective portion 160, the pixel electrode 114 may be formed on the inclined surface 140s of the second pattern portion 140 when the pixel electrode 114 is formed. In this case, light may be emitted even on the inclined surface 140s of the second pattern portion 140, and the emitted light may be emitted toward a subpixel SP (e.g., the first subpixel SP1) of a different color, causing color mixing.

Therefore, in the display apparatus 100 according to one implementation of the present disclosure, color mixing can be prevented by positioning the pixel electrode 114 of each of the plurality of subpixels SP apart from the second reflective portion 160.

Meanwhile, the second reflective portion 160 may be partially positioned closer to the substrate 110 than the pixel electrode 114. For example, as shown in FIG. 4, the second flat reflective portion 161 and a portion of the second inclined reflective portion 162 of the second reflective portion 160 may be positioned closer to the substrate 110 than the pixel electrode 114. The display apparatus 100 according to one implementation of the present disclosure is a bottom-emitting type, and light extraction efficiency can be improved through the second reflective portion 160 (or the second inclined reflective portion 162) on the second pattern portion 140 concavely formed on the outer side of a subpixel SP. Accordingly, the display apparatus 100 according to one implementation of the present disclosure may have a structural feature in which the second flat reflective portion 161 and the portion of the second inclined reflective portion 162 of the second reflective portion 160 are positioned closer to the substrate 110 than to the pixel electrode 114.

As a result, the display apparatus 100 according to one implementation of the present disclosure can improve light efficiency by allowing light extraction even in the first non-light emission area NEA1 where the wiring 120 is arranged, since the first reflective portion 150 is provided between the pixel electrodes 114 located inner side of one subpixel SP.

In addition, the display apparatus 100 according to one implementation of the present disclosure has the second reflective portion 160 provided between pixel electrodes 114 of each of the plurality of subpixels SP that emit different colors among the plurality of subpixels SP, so that light directed toward an adjacent subpixel SP can be reflected in a frontal direction, thereby preventing color mixing and improving light extraction efficiency.

In addition, since the display apparatus 100 according to one implementation of the present disclosure is provided such that the wiring 120 partially overlaps the first non-light emission area NEA1 where light is not emitted, the size (or area) of the circuit area can be reduced compared to a general display apparatus, and thus the size (or area) of the light emission area EA can be relatively expanded. Accordingly, the display apparatus 100 according to one implementation of the present disclosure can have improved light efficiency due to an expansion of the size (or area) of the light emission area EA.

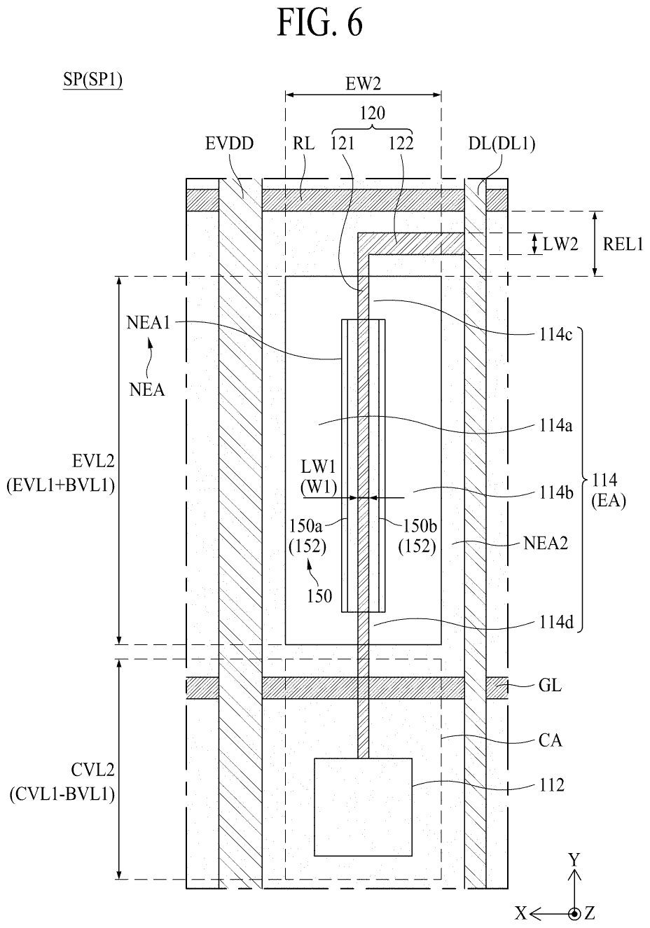

FIG. 5 is a schematic plan view showing one subpixel of a display apparatus according to a comparative example, and FIG. 6 is a schematic plan view showing one subpixel (for example, the first subpixel SP1) of the display apparatus according to one implementation of the present disclosure.

Referring to FIG. 5, a light-emission area EA (or pixel electrode PE) of a display apparatus according to a comparative example can be provided between a circuit area CA and a reference wiring RL in a first direction (Y-axis direction). Additionally, the light-emission area EA (or pixel electrode PE) of the display apparatus according to the comparative example may be provided between a pixel power wiring EVDD and a data wiring DL in a second direction (X-axis direction). Accordingly, the light-emission area EA (or pixel electrode PE) of the display apparatus according to the comparative example may be provided with a size (or area) having a first light-emitting length EVL1 in the first direction (Y-axis direction) and a first width EW1 in the second direction (X-axis direction).

The light-emission area EA of the display apparatus according to the comparative example may be provided spaced apart from the reference wiring RL by a first upper length REL1 in the first direction (Y-axis direction). The first upper length REL1 may be the length of an upper process margin area for forming the reference wiring RL. Additionally, the light-emission area EA may be provided spaced apart from the gate wiring GL by a first lower length BVL1 or more. The first lower length BVL1 may be the length of a lower process margin region for forming the gate wiring GL.

Meanwhile, the circuit area CA of the display apparatus according to the comparative example may be provided with a size (or area) including a thin film transistor TFT and a data branch wiring BRL. As shown in FIG. 5, the data branch wiring BRL may include a first data branch wiring BRL1 connected to the thin film transistor TFT, and a second data branch wiring BRL2 connected to the first data branch wiring BRL1 and the data wiring DL. The first data branch wiring BRL1 can extend in the first direction (Y-axis direction), and the second data branch wiring BRL2 can extend in the second direction (X-axis direction). Accordingly, the circuit area CA of the display apparatus according to the comparative example may be provided with a size (or area) having a first circuit length CVL1 in the first direction (Y-axis direction) and a first width EW1 in the second direction (X-axis direction).

As a result, in the case of the display apparatus according to the comparative example, since the data branch wiring BRL is placed in the circuit area CA, there is a limit to expanding the size (or area) of the light-emission area EA, making it difficult to improve the light efficiency.

In contrast, in the display apparatus 100 according to one implementation of the present disclosure, the wiring 120 is arranged to partially overlap the first non-light emission area NEA1 located inner side of the subpixel SP, so that the size (or area) of the circuit area CA can be reduced, and thus the size (or area) of the light emission area EA can be relatively expanded.

For example, as shown in FIG. 6, the first wiring 121 may extend from the thin film transistor 112 in the first direction (Y-axis direction) and partially overlap the light-emission area EA and the first non-light emission area NEA1. Then, the first wiring 121 may be connected to a second wiring 122 between the light-emission area EA and the reference wiring RL. The second wiring 122 may extend in the second direction (X-axis direction) and be connected to the data wiring DL (e.g., the first data wiring DL1).

Therefore, in the display apparatus 100 according to one implementation of the present disclosure, since the second wiring 122 is arranged in the upper process margin area, the size of the circuit area CA can be reduced compared to the comparative example in which the second data branch wiring BRL2 is provided in the circuit area CA. A width of the second wiring 122 may be smaller than the upper process margin area. Accordingly, in the display apparatus 100 according to one implementation of the present disclosure, the second wiring 122 may be placed in the upper process margin area.

As the second wiring 122 is arranged in the upper process margin area, the circuit area CA may be provided with a size (or area) having a second circuit length CVL2 in the first direction (Y-axis direction) and a second width EW2 in the second direction (X-axis direction). The second circuit length CVL2 may be a length obtained by subtracting the first lower length BVL1 from the first circuit length CVL1. The second width EW2 may be equal to the first width EW1.

Therefore, the display apparatus 100 according to one implementation of the present disclosure may have a smaller size (or area) of the circuit area CA than the display apparatus according to the comparative example. Therefore, the display apparatus 100 according to one implementation of the present disclosure may have an expanded size (or area) of the light-emission area EA.

For example, the light-emission area EA may be provided with a size (or area) having a second light-emitting length EVL2 in the first direction (Y-axis direction) and a second width EW2 in the second direction (X-axis direction). The second light-emitting length EVL2 may be a length that is the sum of the first light-emitting length EVL1 and the first lower length BVL1. The second width EW2 may be the same as the first width EW1.

Meanwhile, in the display apparatus 100 according to one implementation of the present disclosure, the first non-light emission area NEA1 is provided on the inner side of the light emission area EA, but since light extraction can be achieved by the first reflective portion 150, a reduction in light efficiency can be minimal.

As a result, the display apparatus 100 according to one implementation of the present disclosure is provided such that the wiring 120 partially overlaps the first non-light emission area NEA1 and the light emission area EA, so that the size (or area) of the light emission area EA can be expanded compared to the display apparatus according to the comparative example, thereby improving the light efficiency.

Referring to FIG. 6, a width LW1 (or W1) of the first wiring 121 may be provided to be narrower than a width of the first non-light emission area NEA1. If the width LW1 (or W1) of the first wiring 121 is equal to or larger than the width of the first non-light emission area NEA1, the light reflected by the first reflective portion 150 is blocked, thereby reducing the light efficiency. Accordingly, in the display apparatus 100 according to one implementation of the present disclosure, the width LW1 (or W1) of the first wiring 121 is provided to be narrower than the width of the first non-light emission area NEA1, thereby preventing a decrease in light efficiency.

A width LW2 of the second wiring 122 may be provided to be smaller than a second upper length REL2. The second upper length REL2 may be equal to the first upper length REL1. If the width LW2 of the second wiring 122 is the same as the second upper length REL2, the manufacturing process may be difficult, and if the width of the second wiring 122 is greater than the second upper length REL2, the light emission area EA may be covered, which may reduce light efficiency. Accordingly, the display apparatus 100 according to one implementation of the present disclosure may be manufactured in an easy manner and a decrease in light efficiency may be prevented by providing the width LW2 of the second wiring 122 to be smaller than the second upper length REL2.

The display apparatus 100 according to one implementation of the present disclosure may have the pixel electrode 114 provided in each light-emission area EA of the plurality of subpixels SP. According to one example, the pixel electrode 114 may be provided in a closed loop shape or a horseshoe shape with one side open.

For example, as shown in FIG. 6, the pixel electrode 114 may be provided in a closed loop form. Here, the pixel electrode 114 may include a first pixel electrode 114a, a second pixel electrode 114b, a third pixel electrode 114c, and a fourth pixel electrode 114d.

The first pixel electrode 114a may be positioned apart from one side 150a of the first reflective portion 150. For example, the one side 150a of the first reflective portion 150 may mean the uppermost side of the first inclined reflective portion 152 located on a left side of the first flat reflective portion 151 with reference to FIG. 4. The second pixel electrode 114b may be positioned apart from an other side 150b of the first reflective portion 150. The other side 150b of the first reflective portion 150 may mean the uppermost side of the first inclined reflective portion 152 located on a right side of the first flat reflective portion 151 with reference to FIG. 4. The third pixel electrode 114c can connect one side (e.g., an upper side of the first pixel electrode 114a based on FIG. 6) of the first pixel electrode 114a and one side (e.g., an upper side of the second pixel electrode 114b based on FIG. 6) of the second pixel electrode 114b. The fourth pixel electrode 114d can connect an other side (e.g., a lower side of the first pixel electrode 114a based on FIG. 6) of the first pixel electrode 114a and an other side (e.g., the lower side of the second pixel electrode 114b based on FIG. 6) of the second pixel electrode 114b.

Therefore, the display apparatus 100 according to one implementation of the present disclosure may be provided with pixel electrodes 114 of each of the plurality of subpixels SP in a closed loop shape when viewed from a plane. In this case, the wiring 120 may partially overlap two or more of the first pixel electrode 114a, the second pixel electrode 114b, the third pixel electrode 114c, and the fourth pixel electrode 114d.

For example, as shown in FIG. 6, the first wiring 121 may be arranged between the first pixel electrode 114a and the second pixel electrode 114b. And, the first wiring 121 may extend in the first direction (Y-axis direction). Accordingly, the first wiring 121 may partially overlap with each of the third pixel electrode 114c and the fourth pixel electrode 114d. In contrast, the second wiring 122 may be connected to the first wiring 121 and arranged in a different direction from the first wiring 121. For example, the second wiring 122 may be arranged to extend in the second direction (X-axis direction) while being connected to an end of the first wiring 121 protruding into the upper process margin area. Accordingly, the second wiring 122 may not overlap with the pixel electrode 114. Therefore, in the display apparatus 100 according to one implementation of the present disclosure, the size (or area) of the light-emission area EA may be expanded by the first lower length BVL1 compared to the display apparatus according to the comparative example, and thus the light efficiency may be improved.

Meanwhile, in the display apparatus 100 according to one implementation of the present disclosure, the width LW1 (or W1) of the first wiring 121 may be narrower than the width LW2 of the second wiring 122. As described above, since the first wiring 121 partially overlaps the first non-light emission area NEA1 where the first reflective portion 150 is arranged, if the width LW1 (or W1) of the first wiring 121 is equal to or wider than the width LW2 of the second wiring 122, a light reflected by the first reflective portion 150 can be blocked. In contrast, since the second wiring 122 is arranged in the upper process margin area that is relatively wider than a width of the first non-light emission area NEA1 in the second direction (X-axis direction), it may be provided with a wider width than the first wiring 121. Accordingly, the display apparatus 100 according to one implementation of the present disclosure may have a structural feature in which the width LW1 (or W1) of the first wiring 121 is provided narrower than the width LW2 of the second wiring 122.

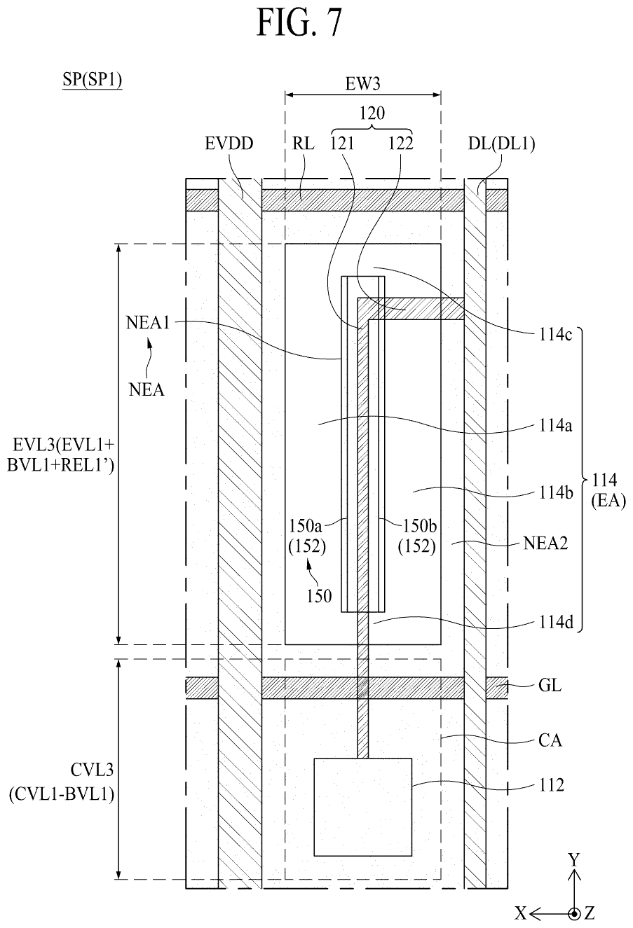

FIG. 7 is a schematic plan view showing one subpixel of the display apparatus according to the second implementation of the present disclosure.

Referring to FIG. 7, the display apparatus 100 according to the second implementation of the present disclosure is the same as the display apparatus according to FIG. 6 described above, except that a structure of the pixel electrode 114 and the wiring 120 is changed. Therefore, the same drawing reference numerals are given to the same configurations, and only different configurations will be described below.

In the case of the display apparatus according to FIG. 6, the first wiring 121 partially overlaps with each of the third pixel electrode 114c and the fourth pixel electrode 114d. In addition, the second wiring 122 may be provided in the upper process margin area so as not to overlap with the pixel electrode 114. Accordingly, in the case of the display apparatus according to FIG. 6, the size of the circuit area CA can be reduced compared to the comparative example in which the second data branch wiring BRL2 is provided in the circuit area CA. And, in the case of the display apparatus according to FIG. 6, the size (or area) of the light-emission area EA can be expanded as the size of the circuit area CA is reduced. For example, in the case of the display apparatus according to FIG. 6, the light-emission area EA may be provided with a size (or area) having a second light-emitting length EVL2 in the first direction (Y-axis direction) and a second width EW2 in the second direction (X-axis direction). The second light-emitting length EVL2 may be a length that is the sum of the first light-emitting length EVL1 and the first lower length BVL1. The second width EW2 may be equal to the first width EW1. Accordingly, in the case of the display apparatus according to FIG. 6, the size (or area) of the light-emission area EA may be expanded compared to the display apparatus according to the comparative example, so that the light efficiency may be improved.

In contrast, in the case of the display apparatus according to FIG. 7, the first wiring 121 may partially overlap the fourth pixel electrode 114d, and the second wiring 122 may partially overlap the second pixel electrode 114b. For example, as shown in FIG. 7, the first wiring 121 may extend from the thin film transistor 112 and partially overlap the fourth pixel electrode 114d. And, an end of the first wiring 121 may be arranged in the first non-light emission area NEA1. The second wiring 122 may be connected to the end of the first wiring 121 in the first non-light emission area NEA1 and may extend in the second direction (X-axis direction) to be connected to the data wiring DL. Accordingly, the second wiring 122 may partially overlap the second pixel electrode 114b. Therefore, in the case of the display apparatus according to FIG. 7, since the second wiring 122 is not provided in the upper process margin area, the size (or area) of the light-emission area EA can be further expanded in the first direction (Y-axis direction).

For example, in the case of the display apparatus according to FIG. 7, the light emission area EA may be provided with a size (or area) having a third light-emitting length EVL3 in the first direction (Y-axis direction) and a third width EW3 in the second direction (X-axis direction). The third light-emitting length EVL3 may be a sum of the first light-emitting length EVL1, the first lower length BVL1, and a first′ upper length REL1′. The first′ upper length REL1′ may be shorter than the first upper length REL1. This is because when the first′ upper length REL1′ is equal to or longer than the first upper length REL1, the pixel electrode 114 overlaps with the reference wiring RL, thereby reducing light efficiency. The third width EW3 may be equal to the first width EW1. Accordingly, in the case of the display apparatus according to FIG. 7, a size (or area) of the light-emission area EA may be further expanded in the first direction (Y-axis direction) compared to the display apparatus according to FIG. 6, so that light efficiency may be improved.

Meanwhile, as shown in FIG. 7, the circuit area CA of the display apparatus 100 according to the second implementation of the present disclosure may be provided with a size (or area) having a third circuit length CVL3 in the first direction (Y-axis direction) and a second width EW3 in the second direction (X-axis direction). The third circuit length CVL3 may be a length obtained by subtracting the first lower length BVL1 from the first circuit length CVL1. The third width EW3 may be equal to the first width EW1.

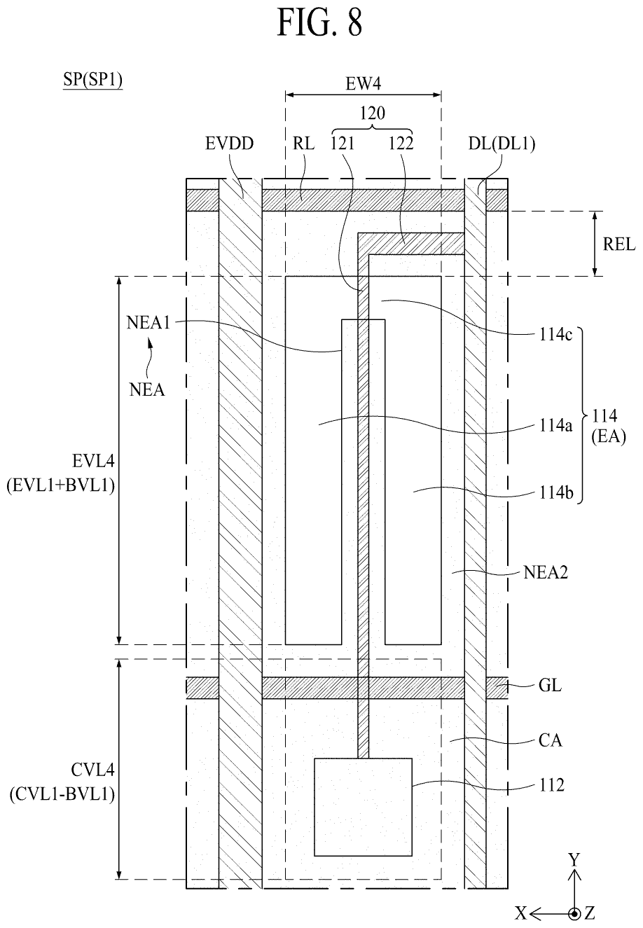

FIG. 8 is a schematic plan view showing one subpixel of the display apparatus according to the third implementation of the present disclosure.

Referring to FIG. 8, the display apparatus 100 according to the third implementation of the present disclosure is the same as the display apparatus according to FIG. 6 described above, except that a structure of the pixel electrode 114 is changed. Therefore, the same drawing reference numerals are given to the same configurations, and only different configurations will be described below.

In the case of the display apparatus according to FIG. 6, the pixel electrode 114 is provided in a closed loop form. Therefore, in the case of the display apparatus according to FIG. 6, the first wiring 121 partially overlaps with each of the third pixel electrode 114c and the fourth pixel electrode 114d. In addition, the second wiring 122 may be provided in the upper process margin area so as not to overlap with the pixel electrode 114. Therefore, in the case of the display apparatus according to FIG. 6, the size of the circuit area CA can be reduced compared to the display apparatus according to the comparative example, and thus the size (or area) of the light-emission area EA can be relatively expanded.

For example, in the case of the display apparatus according to FIG. 6, the light emission area EA may be provided with a size (or area) having the second light-emitting length EVL2 in the first direction (Y-axis direction) and the second width EW2 in the second direction (X-axis direction). The second light emitting length EVL2 may be a length obtained by adding the first lower length BVL1 to the first light-emitting length EVL1. The second width EW2 may be equal to the first width EW1. Therefore, in the case of the display apparatus according to FIG. 6, the size (or area) of the light emission area EA may be expanded compared to the display apparatus according to the comparative example, so that the light efficiency may be improved.

In contrast, in the case of the display apparatus according to FIG. 8, the pixel electrode 114 may be provided in a horseshoe shape with one side open. For example, in the case of the display apparatus according to FIG. 8, the fourth pixel electrode 114d may be provided in a structure in which it is omitted. Accordingly, the display apparatus 100 according to FIG. 8 may be provided with pixel electrodes 114 in the form of a first pixel electrode 114a, a second pixel electrode 114b, and a third pixel electrode 114c. As shown in FIG. 8, since the pixel electrodes 114 are provided in a horseshoe shape, the first non-light emission area NEA1 may be connected to the second non-light emission area NEA2.

In the case of the display apparatus according to FIG. 8, the wiring 120 may partially overlap with one of the first pixel electrode 114a, the second pixel electrode 114b, and the third pixel electrode 114c. For example, as shown in FIG. 8, the first wiring 121 may extend from the thin film transistor 112 in the first direction (Y-axis direction) and partially overlap with the third pixel electrode 114c. And, an end of the first wiring 121 may be arranged in the upper process margin area. The second wiring 122 may be connected to the end of the first wiring 121 protruding into the upper process margin area. And, the second wiring 122 may be extended in the second direction (X-axis direction) to be connected to the data wiring DL. Therefore, the second wiring 122 may not overlap the pixel electrode 114. Therefore, in the case of the display apparatus according to FIG. 8, a size (or area) of the light-emission area EA may be expanded by the first lower length BVL1 compared to the display apparatus according to the comparative example, so that the light efficiency may be improved.

For example, in the case of the display apparatus according to FIG. 8, the light emission area EA may be provided with a size (or area) having a fourth light-emitting length EVL4 in the first direction (Y-axis direction) and a fourth width EW4 in the second direction (X-axis direction). The fourth light-emitting length EVL4 may be a length that is the sum of the first light-emitting length EVL1 and the first lower length BVL1. The fourth width EW4 may be equal to the first width EW1. Accordingly, in the case of the display apparatus according to FIG. 8, a size (or area) of the light-emission area EA can be further expanded in the first direction (Y-axis direction) compared to the display apparatus according to the comparative example, so that the light efficiency can be improved.

Meanwhile, as shown in FIG. 8, the circuit area CA of the display apparatus 100 according to the third implementation of the present disclosure may be provided with a size (or area) having a fourth circuit length CVL4 in the first direction (Y-axis direction) and a fourth width EW4 in the second direction (X-axis direction). The fourth circuit length CVL4 may be a length obtained by subtracting the first lower length BVL1 from the first circuit length CVL1. The fourth width EW4)may be equal to the first width EW1.

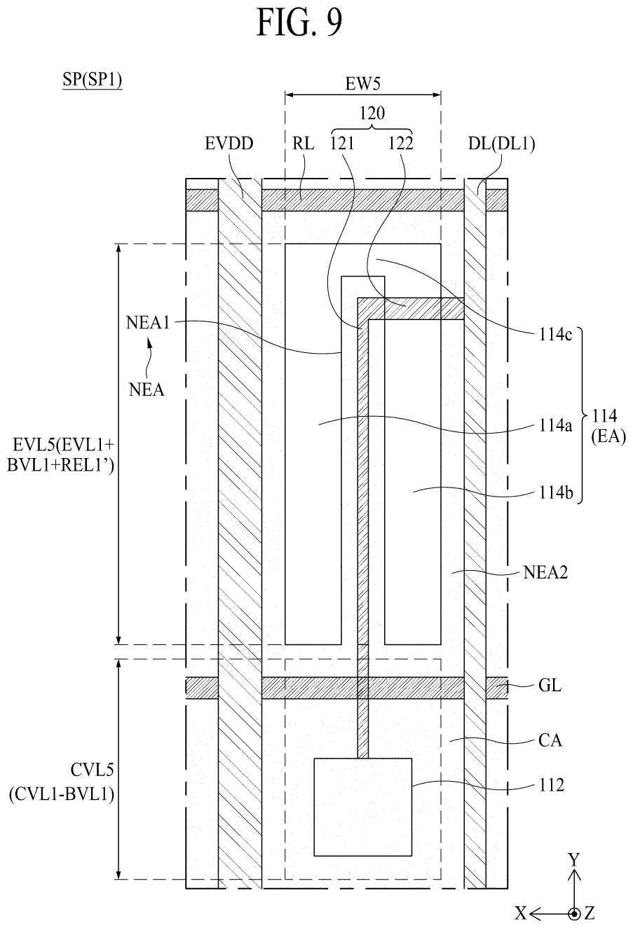

FIG. 9 is a schematic plan view showing one subpixel of the display apparatus according to the fourth implementation of the present disclosure.

Referring to FIG. 9, the display apparatus 100 according to the fourth implementation of the present disclosure is the same as the display apparatus according to FIG. 7 described above, except that a structure of the pixel electrode 114 is changed. Therefore, the same reference numerals are given to the same configurations, and only different configurations will be described below.

In the case of the display apparatus according to FIG. 7, the pixel electrode 114 is provided in a closed loop form. Therefore, in the case of the display apparatus according to FIG. 7, the first wiring 121 may partially overlap with the fourth pixel electrode 114d, and the second wiring 122 may partially overlap with the second pixel electrode 114b. Therefore, in the case of the display apparatus according to FIG. 7, since the second wiring 122 is not provided in the upper process margin area, a size (or area) of the light-emission area EA can be further expanded in the first direction (Y-axis direction) compared to the case where the second wiring is provided in the upper process margin area.

In contrast, in the case of the display apparatus according to FIG. 9, the pixel electrode 114 may be provided in a horseshoe shape with one side open. For example, in the case of the display apparatus according to FIG. 9, the fourth pixel electrode 114d may be provided in a structure in which it is omitted. Accordingly, the display apparatus 100 according to FIG. 9 may be provided with pixel electrodes 114 in the form of a first pixel electrode 114a, a second pixel electrode 114b, and a third pixel electrode 114c. As shown in FIG. 9, since the pixel electrodes 114 are provided in a horseshoe shape, the first non-light emission area NEA1 may be connected to the second non-light emission area NEA2.

In the case of the display apparatus according to FIG. 9, the wiring 120 may partially overlap with one of the first pixel electrode 114a, the second pixel electrode 114b, and the third pixel electrode 114c. For example, as shown in FIG. 9, the first wiring 121 may extend from the thin film transistor 112 in the first direction (Y-axis direction) and have its end positioned in the first non-light emission area NEA1. Therefore, the first wiring 121 may not overlap with the pixel electrode 114. The second wiring 122 may be connected to an end of the first wiring 121 in the first non-light emission area NEA1. And, the second wiring 122 can be extended in the second direction (X-axis direction) and connected to the data wiring DL. Therefore, the second wiring 122 can partially overlap the second pixel electrode 114b. Therefore, in the case of the display apparatus according to FIG. 9, since the second wiring 122 is not provided in the upper process margin area, a size (or area) of the light-emission area EA can be further expanded in the first direction (Y-axis direction).

For example, in the case of the display apparatus according to FIG. 9, the light emission area EA may be provided with a size (or area) having a fifth light-emitting length EVL5 in the first direction (Y-axis direction) and a fifth width EW5 in the second direction (X-axis direction). The fifth light-emitting length EVL5 may be a length that is the sum of the first light emitting length EVL1, the first lower length BVL1, and the first′ upper length REL1′. The first′ upper length REL1′ may be shorter than the first upper length REL1. If the first′ upper length REL1′ is equal to or longer than the first upper length REL1, the pixel electrode 114 overlaps with the reference wiring RL, thereby reducing light efficiency. The fifth width EW5 may be equal to the first width EW1. Accordingly, in the case of the display apparatus according to FIG. 9, a size (or area) of the light-emission area EA can be further expanded in the first direction (Y-axis direction) compared to the case where the second wiring 122 is provided in the upper process margin area, so that the light efficiency can be further improved.

Meanwhile, as shown in FIG. 9, the circuit area CA of the display apparatus 100 according to the fourth implementation of the present disclosure may be provided with a size (or area) having a fifth circuit length CVL5 in the first direction (Y-axis direction) and a fifth width EW5 in the second direction (X-axis direction). The fifth circuit length CVL5 may be a length obtained by subtracting the first lower length BVL1 from the first circuit length CVL1. The fifth width EW5 may be equal to the first width EW1.

As shown in FIG. 6, a display apparatus 100 according to one implementation of the present disclosure may have the best light efficiency compared to other implementations by having the first wiring 121 narrower than the second wiring 122 partially overlap with the third pixel electrode 114c and the fourth pixel electrode 114d. That is, the display apparatus 100 according to one implementation of the present disclosure has two screen areas where the light-emission area EA is covered by the first wire 121, but since an area of the screen area is the smallest compared to other implementations, the light efficiency may be the best compared to other implementations.

As shown in FIG. 8, the display apparatus 100 according to the third implementation of the present disclosure has a screen area only once since the pixel electrode 114 is in a horseshoe shape, but the fourth pixel electrode 114d is omitted, so the light efficiency (or luminous efficiency) may be lower than that of the display apparatus 100 according to one implementation.

Meanwhile, as shown in FIG. 7, the display apparatus 100 according to the second implementation of the present disclosure has the pixel electrode 114 (or light-emission area EA) in a closed loop form and is provided with a size (or area) that extends to a part of the upper process margin area, so that the area of the pixel electrode 114 (or light-emission area EA) can be the largest compared to other implementations. Accordingly, the display apparatus 100 according to the second implementation of the present disclosure has the largest area of the pixel electrode 114 (or the light-emission area EA) compared to other implementations, and thus can have the lowest current density during driving, and thus can have the longest service life.

Implementations of the present disclosure have been described in more detail with reference to the accompanying drawings, but the present disclosure is not necessarily limited to these implementations and may be practiced in various modifications without departing from the technical ideas of the present disclosure. Accordingly, the implementations disclosed herein are intended to illustrate, not limit, the technical ideas of the present disclosure, and the scope of the technical ideas of the present disclosure is not limited by these implementations. Therefore, the implementations described above are exemplary in all respects and should be understood as non-limiting. All technical ideas within the scope of protection of this disclosure should be construed to be included within the scope of the claims of this disclosure.

The display apparatus according to the present disclosure is provided such that wiring for driving each of the plurality of sub-pixels partially overlaps the non-light emission area (or the first non-light emission area) provided on the inside of each of the plurality of sub-pixels, thereby allowing the size (or area) of the light emission area to be expanded.

The display apparatus according to the present disclosure can have improved light efficiency due to expansion of the size (or area) of the light-light emission area.

The display apparatus according to the present disclosure is provided with the reflective portion (or the first reflective portion) arranged in the non-light emission area (or the first non-light emission area) provided on the inner side of each of the plurality of subpixels, so that the light extraction efficiency of light emitted from the light-emitting element layer can be improved.

The display apparatus according to the present disclosure is provided with the reflective portion (or the second reflective portion) arranged in the non-light emission area (or the second non-light emission area) provided on the outer side of the plurality of sub-pixels, so that the reflective portion (or the second reflective portion) can reflect light directed toward an adjacent sub-pixel, thereby improving light extraction efficiency.

Since the display apparatus according to the present disclosure can extract light even in the non-light emission area through the reflective portions (or the first reflective portion and the second reflective portion) provided on the inner and outer sides of each of the plurality of subpixels, the display apparatus can have the same luminous efficiency or can have the luminous efficiency improved to a higher degree even with lower power compared to a display apparatus having no reflective portions on the inner and outer sides of each of the plurality of subpixels, so that the overall power consumption can be reduced.

The effects to be obtained from the present disclosure are not limited to those mentioned above, and other effects not mentioned will be apparent to one of ordinary skill in the art from the description.

What is claimed is:

1. A display apparatus comprising:
a substrate comprising a plurality of pixels, each pixel having a plurality of subpixels;
a light emission area provided on the substrate for each of the plurality of subpixels; and
a wiring partially overlapping the light-emission area.

2. The display apparatus of claim 1, comprising a thin film transistor configured to drive each of the plurality of sub-pixels,
wherein the wiring comprises a branch wiring connected to the thin film transistor.

3. The display apparatus of claim 2, wherein the branch wiring includes a data branch wiring.

4. The display apparatus of claim 1, comprising a second non-light emission area provided on the substrate and is located an outer side of each of the plurality of subpixels,
wherein the second non-light emission area comprises:
a first planarization layer provided on the substrate;
a second planarization layer provided on the first planarization layer;
a second pattern portion concavely formed in the second planarization layer; and
a second reflective portion provided on the second pattern portion.

5. The display apparatus of claim 4, wherein the first planarization layer has a different refractive index from the second planarization layer.

6. The display apparatus of claim 4, wherein the second reflective portion is provided between pixel electrodes of each of the plurality of subpixels that emit different colors among the plurality of subpixels.

7. The display apparatus of claim 4, wherein each of the plurality of subpixels includes a pixel electrode arranged spaced apart from the second reflective portion, and the second reflective portion is partially arranged closer to the substrate than the pixel electrode.

8. The display apparatus of claim 4, wherein the second reflective portion comprises:
a second flat reflective portion arranged parallel to an upper surface of the substrate; and
a second inclined reflective portion connected to the second flat reflective portion and provided at an angle, and
wherein the substrate comprises a data wiring partially overlapping the second flat reflective portion, and
wherein the data wiring is connected to the wiring.

9. The display apparatus of claim 4, wherein each of the plurality of subpixels includes a first non-light emission area inside the light emission area, and the wiring partially overlaps the first non-light emission area.

10. The display apparatus of claim 9, wherein the first non-light-emission area comprises:
a first pattern portion concavely formed on the second planarization layer; and
a first reflective portion provided on the first pattern portion.

11. The display apparatus of claim 10, wherein each of the plurality of subpixels includes a pixel electrode arranged spaced apart from the first reflective portion, and the first reflective portion is partially arranged closer to the substrate than the pixel electrode.

12. The display apparatus of claim 10, wherein the first reflective portion comprises:
a first flat reflective portion arranged parallel to an upper surface of the substrate; and
a first inclined reflective portion connected to the first flat reflective portion and provided at an angle, and
wherein the wiring overlaps the first flat reflective portion.

13. The display apparatus of claim 12, wherein a width of the wiring is equal to or narrower than a width of the first flat reflective portion.

14. The display apparatus of claim 10, wherein each of the plurality of subpixels includes a pixel electrode provided in the light-emission area, and
wherein the pixel electrode includes:
a first pixel electrode arranged spaced apart from one side of the first reflective portion;
a second pixel electrode arranged spaced apart from an other side of the first reflective portion;
a third pixel electrode connecting one side of the first pixel electrode and one side of the second pixel electrode; and
a fourth pixel electrode connecting an other side of the first pixel electrode and an other side of the second pixel electrode, and
wherein the wiring partially overlaps two or more of the first pixel electrode, the second pixel electrode, the third pixel electrode, and the fourth pixel electrode.

15. The display apparatus of claim 14, wherein the wiring includes:
a first wiring arranged between the first pixel electrode and the second pixel electrode; and
a second wiring connected to the first wiring and arranged in a different direction from the first wiring, and
wherein the first wiring partially overlaps the fourth pixel electrode, and the second wiring partially overlaps the second pixel electrode.

16. The display apparatus of claim 15, wherein the plurality of sub-pixels includes:
a first subpixel;
a second subpixel adjacent to the first sub-pixel in a second direction; and
a third subpixel adjacent to the second sub-pixel in the second direction,
wherein the first subpixel is a red subpixel, the second subpixel is a green subpixel, and the third subpixel is a blue subpixel.

17. The display apparatus of claim 16, wherein the plurality of sub-pixels include a data wiring arranged in a first direction between the first subpixel and the second subpixel, and the second wiring partially overlaps the data wiring.

18. The display apparatus of claim 16, wherein the plurality of sub-pixels include a bank covering edges on both sides of the pixel electrode in the first direction,
wherein the bank is not arranged between the first subpixel and the second subpixel, and is not arranged between the second subpixel and the third subpixel.

19. The display apparatus of claim 17, wherein each of the plurality of sub-pixels comprises:
a circuit area provided on one side of the light-emission area and including a thin film transistor; and
a gate wiring arranged in the second direction between the light-emission area and the circuit area.

20. The display apparatus of claim 19, wherein the first subpixel includes a pixel power wiring arranged parallel to the data wiring with the light-emission area interposed therebetween, and the gate wiring partially overlaps each of the pixel power wiring and the data wiring.
